(19) United States
(12) Patent Application Publication
(10) Pub. No.: US 2006/0181346 A1
(43) Pub. Date: Aug. 17, 2006

(54) Constant frequency self-oscillating amplifier

(76) Inventor: Tranh To Nguyen, Rohnert Park, CA (US)

Correspondence Address: Tranh Nguyen, 1552 Magnolia Avenue, Rohnert Park, CA, 94928, US

(21) Appl. No.: 11/355,453

(22) Filed: Feb. 15, 2006

Related U.S. Application Data
(60) Provisional application No. 60/654,059, filed on Feb. 16, 2005.

(51) Int. Cl. H03F 3/217

(52) U.S. Cl. 330/251

(57) ABSTRACT

A self-oscillating switch-mode amplifier amplifying an input signal into a power output signal comprising an integrator for integrating the difference between the input signal and the output signal and a hysteretic comparator with thresholds which are modulated according to absolute value of the input signal. When the thresholds are quadratic function of the absolute value of the input signal, the switching frequency of the self-oscillating amplifier can be substantially constant.

### CROSS-REFERENCES TO RELATED APPLICATIONS

This application claims the benefit of U.S. Provisional Application No. 60/654,059 filed Feb. 16, 2005.

### FIELD OF THE INVENTION

The present invention relates to the technical field of signal modulation and amplification, and more particularly, to a self-oscillating amplifier using analog Delta-Sigma modulation.

### BACKGROUND

Typically, analog Delta-Sigma modulation is used for converting an analog input signal to a switching or digital signal by comparing two threshold voltages with an error voltage formed by integrating the difference of the output voltage and the analog signal. When the error voltage exceeds an upper limit represented by the upper threshold voltage, the output changes state to 0. Vice versa, when the error voltage becomes lower than a lower limit represented by the lower threshold voltage, the output is changed to 1. The slope of the error voltage of such a modulator depends on the magnitude of the analog input signal. The higher that magnitude is, the lower the slope of the error voltage, therefore the lower the switching frequency. When the modulation index approaches unity, i.e. the input signal approaches the levels of the output voltage, the switching frequency of the analog Delta-Sigma modulator approaches zero, which results in a digital signal processed by such prior art analog Delta-Sigma modulation to be distorted.

FIG. 1 shows a diagram illustrating prior art analog Delta-Sigma modulation, which includes an integrator 11 and a comparator with hysteresis 12. FIG. 2 shows a comparison of the analog input signal and the digital output signal of prior art analog Delta-Sigma modulation. When the amplitude of the analog input signal is low, the density of the digital output signal is tight, or a high switching frequency. Conversely, when the amplitude of the analog input signal is high, the density of the digital output signal is sparse, or low switching frequency. Therefore, when the frequency of the input signal is high or its amplitude is high, the output signal will be distorted.

Therefore, there is a need an analog Delta-Sigma modulator that can operate at approximately constant switching frequency thus eliminating a major source of distortion in a self-oscillating audio amplifier.

### SUMMARY OF THE INVENTION

An object of the present invention is to provide a switch-mode amplifier using an analog Delta-Sigma modulator capable of operating at substantially constant switching frequency so that its distortion will be lower and its overall efficiency higher.

To achieve the object, the analog Delta-Sigma modulator of the present invention comprises an integrator integrating the difference between an analog input signal and an output feedback signal, providing an error voltage that is compared to modulated hysteresis thresholds to provide a pulse-width modulated signal that has substantially constant switching frequency, driving a switching output stage that can supply high power to a speaker. When the thresholds are quadratic function of the absolute value of the input signal, the switching frequency of the self-oscillating amplifier can be substantially constant.

Other objects, advantages, and novel features of the invention will become more apparent from the following detailed description when taken in conjunction with the accompanying drawings.

### BRIEF DESCRIPTION OF THE DRAWINGS

The present invention, as defined in the claims, can be better understood with reference to the following drawings. The drawings are not necessarily to scale, emphasis instead being placed on clearly illustrating the principles of the present invention.

FIG. 1 is a block diagram of prior art analog Delta-Sigma modulation.

FIG. 2 is a diagram illustrating the analog input signal and the variable frequency switching output signal of prior art Delta-Sigma modulation.

FIG. 3 is a schematic illustrating the preferred embodiment of the present invention.

FIGS. 4A-4D illustrates the waveforms of the envelope of the modulated hysteresis generator in relation to the analog input signal in the present invention.

FIGS. 5A-5C illustrate possible embodiments of the modulated hysteresis generator used in the present invention.

FIGS. 6A-6B are block diagrams illustrating possible additional voltage and current feedback to the self-oscillating amplifier of the present invention.

FIG. 7 is a block diagram illustrating an additional gain block to the constant-frequency self-oscillating amplifier of the present invention.

FIG. 8 illustrates the symbols used in equations 1-6.

FIG. 9 illustrates another embodiment of the constant frequency self-oscillating amplifier of the present invention.

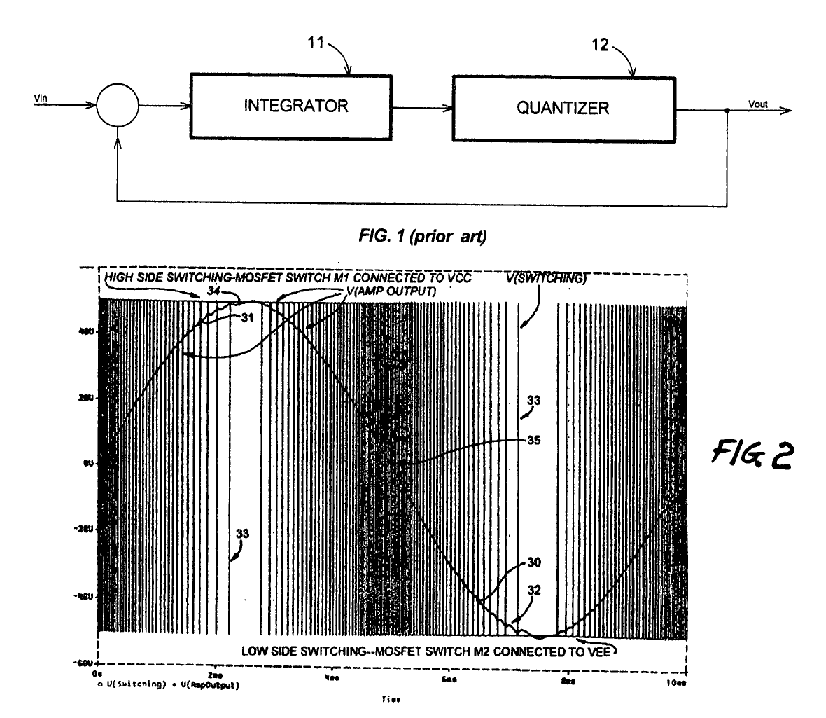

### DETAILED DESCRIPTION OF THE PREFERRED EMBODIMENT

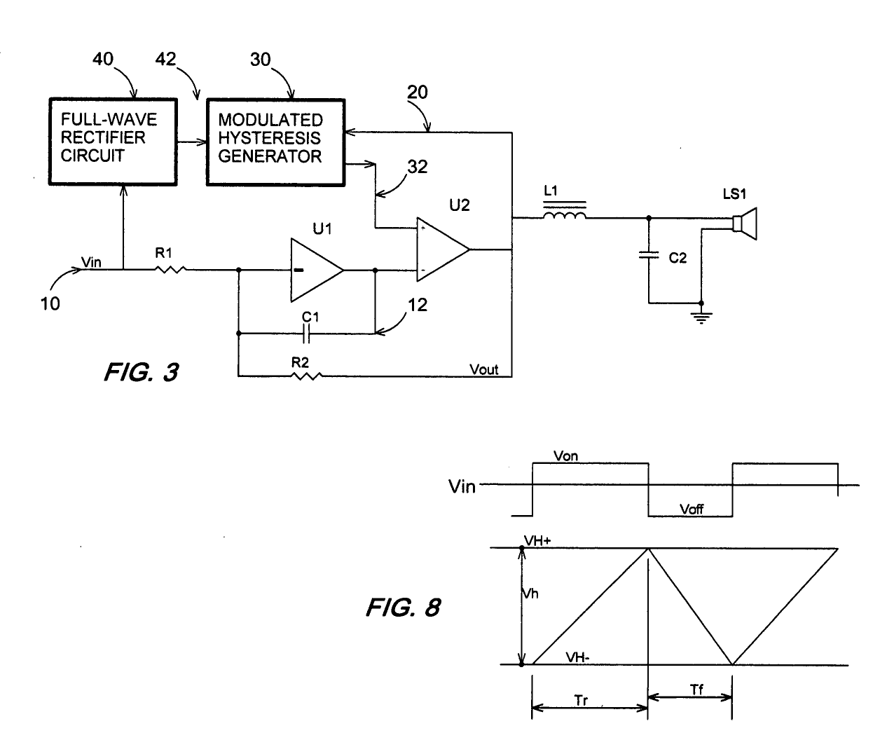

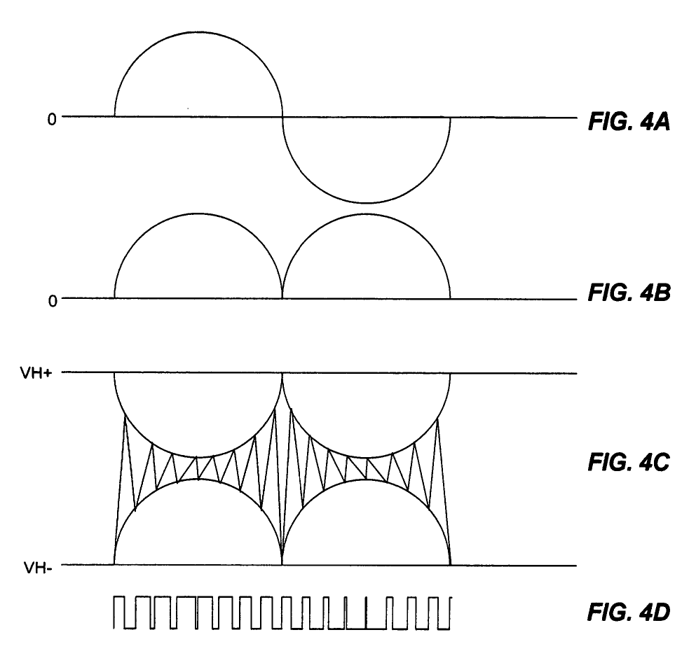

With reference to FIG. 3, the invented constant frequency self-oscillating amplifier (CFSOA) comprises an integrator U1, a full-wave rectifier circuit 40, a power comparator U2, a modulated hysteresis generator 30. The integrator U1 integrates the difference between the analog input signal 10 and the high power switching output signal 20, and puts out an error voltage 12. The full-wave rectifier circuit 40 receives the analog input signal 10 and puts out a positive voltage 42 which is the absolute value of the analog input voltage 10. The modulated hysteresis generator 30 receives the output 42 of the full-wave rectifier circuit 40, the analog input voltage 10, and the output 20 of the comparator U2 to put out a switching voltage, FIG. 4C, the two envelops of which are two mirrored images of the output of the full-wave rectifier circuit 40 offset by predetermined amounts VH+/VH− relative to zero. The output 32 of the modulated hysteresis generator 30 being coupled to an input of the comparator U2 and synchronous with it, effectively makes the comparator U2 acts as a variable hysteresis comparator with the hysteresis voltages 32A and 32B being function of the absolute value 42 of the input voltage 10 to keep the switching frequency of the self-oscillating amplifier substantially constant.

Indeed in a prior art self-oscillating amplifier with feedback from a switching node 20, the switching frequency is lower when the amplitude of the input signal 10 is higher because its switching period comprises two intervals: the first interval Tr is the time it takes the output of the integrator U1 to go from the lower threshold VH− to the higher threshold VH+, and similarly the second interval Tf is the time it takes the output of the integrator U1 to go from the higher threshold VH+ to the lower threshold VH−. Both these intervals are functions of the power supply voltages Von and Voff=−Von and the magnitude of the input signal 10 as seen in the following equations, referring to FIGS. 3 & 8, assuming R1=R2=R; C1=C; and Voff=−Von for simplicity in the explanation:

$$\begin{matrix}Tr = \frac{Vh * R * C}{{V}_{on} - {V}_{in}} & ( 1 ) \\ Tf = \frac{Vh * R * C}{{V}_{on} + {V}_{in}} & ( 2 ) \\ Ts = Tr + Tf = Vh * R * C * ( \frac{1}{{V}_{on} - {V}_{in}} + \frac{1}{{V}_{on} + {V}_{in}} ) & ( 3 )\end{matrix}$$

From Equation (3) the reader can see that Ts is a hyperbolic function of the input voltage Vin if Vh is constant as in the case in prior art Delta-Sigma modulator using a comparator with hysteresis. Equation (3) also shows that when Vin approaches Von in absolute value, the period approaches infinity.

In this invented analog Delta-Sigma modulator, the threshold voltage Vh is generated by the modulated hysteresis generator 30 in a first approach to be equal to |a*(Von−Vin)|. The switching period of the invented modulator then becomes

$$\begin{matrix}Ts = a * R * C * ( {V}_{on} - {V}_{in} ) ( \frac{1}{{V}_{on} - {V}_{in}} + \frac{1}{{V}_{on} + {V}_{in}} ) \\ = K * ( 1 + \frac{{V}_{on} - {V}_{in}}{{V}_{on} + {V}_{in}} )\end{matrix} \qquad ( 4 )$$

Thus when all other parameters are constant, its switching period varies from 2K at quiescent (Vin=0) to 1K at maximum modulation at first order of analysis, or a range of variation of 50%. Practically, switching delays in power semiconductors are proportional to the output current. On the other hand, there are slew rate limitations in real-world operational amplifiers that make them slower when the swing of their output is higher—an op amp large signal bandwidth is usually smaller than its small-signal bandwidth. These two phenomena tend to reduce the range of switching frequency in real-world analog Delta-Sigma modulator implemented according the principles of the present invention. By varying the proportional factor a in the generation of Vh=a*(Von−Vin) with the amplitude of the input voltage Vin, it is possible to make the switching frequency more constant, even though from the EMI standpoint, it is desirable to have some frequency jittering to minimize EMI generation. Thus as a design principle, there are many functions of Vₕ=f(Vᵢₙ) that can be used implement the operation of the modulated hysteresis generator 30 that operates on the amplitude of the input signal 10 to control the range of variation of the switching frequency of the invented self-switch-mode amplifier. For example, let
Vₕ=(Vₒₙ²−Vᵢₙ²)/Vₒₙ=(Vₒₙ+Vᵢₙ)*(Vₒₙ−Vᵢₙ)/Vₒₙ (5)

Substituting (5) in (3) we have:
Tₛ=R*C(Vₒₙ+Vᵢₙ+Vₒₙ−Vᵢₙ)/Vₒₙ=2*R*C (6)

Thus by squaring the amplitude of the input signal Vᵢₙ and subtracting it from an offset voltage to create a hysteresis voltage Vh, constant switching frequency of the invented self-oscillating amplifier can be achieved.

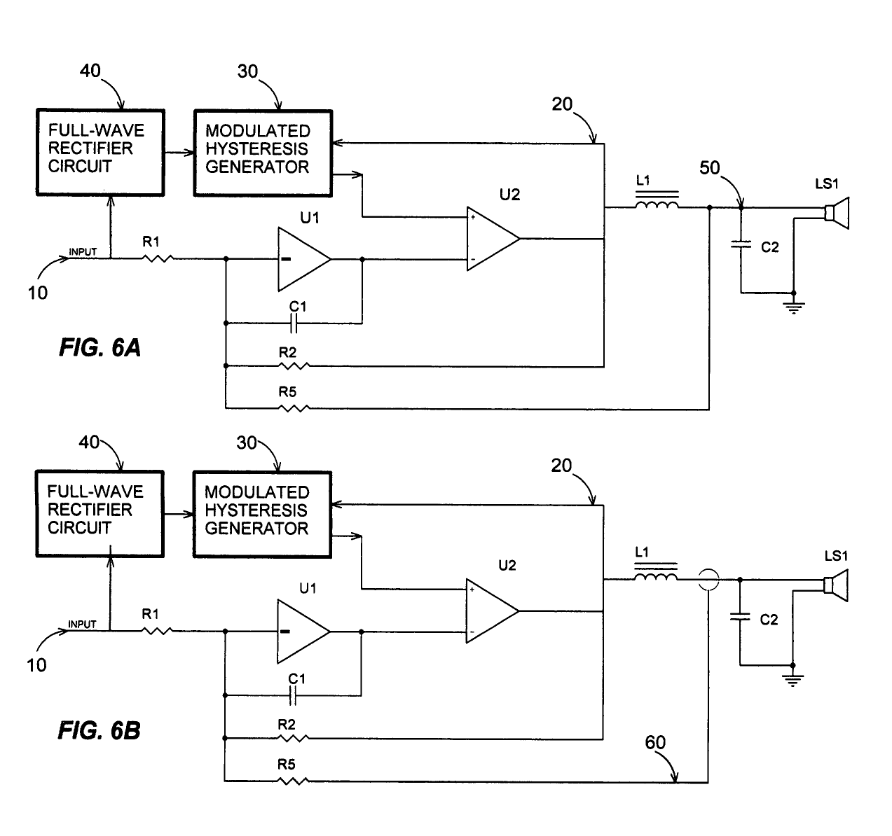

In a second and third embodiment, FIGS. 6A-6B, a signal proportional to the speaker voltage 50 or speaker current 60 or a combination thereof is fed into the integrator U1 to compensate for the resistances and any non-linearities of the components of the reconstruction filter L1-C2. Indeed, a choke used in the reconstruction filter may use a magnetic material for smaller size and lower cost, but magnetic materials are non-linear by their nature, and its winding has finite resistance that actually increases with frequency due to the skin and proximity effects. Likewise, a capacitor has its equivalent series resistance (ESR) and series equivalent inductance (ESL) and its capacitance may vary with applied voltage. While these non-linearities are small, they do degrade the total harmonic distortion (THD) of prior art switch-mode amplifiers. The feedback voltage or current or both voltage and current feedback from the speaker also reduces if not eliminates the peaking of the reconstruction filter L1-C2 when there is an impedance mismatch between the characteristic impedance of the reconstruction filter L1-C2 and the speaker LS1 impedance. Such feedback also reduces the output impedance of the amplifier.

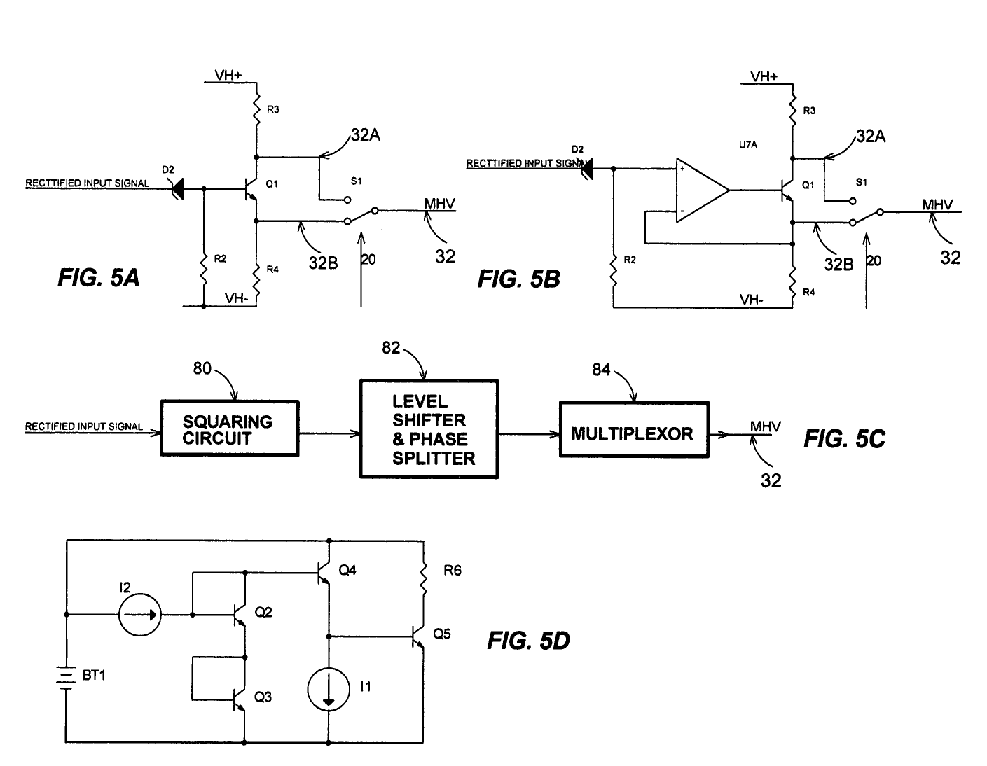

The modulated hysteresis generator 30 can be implemented with level shifter using a Zener diode D2, and a phase splitter comprising a single transistor Q1 and two resistors R3 and R4, FIG. 5A, or its improvement, FIG. 5B. In the circuit of FIG. 5A, the Zener diode D2 provides a level shifting corresponding to the negative term −Vᵢₙ² in equation (5). As the collector current and the emitter current of the transistor Q1 are essentially the same, the envelopes of the two modulated hysteresis voltages 32A and 32B may be mirror image of each other. The analog switch S1 synchronizes the transition of the comparator U2 input voltage in the same fashion as in a comparator with hysteresis via a positive feedback resistor.

FIG. 5C illustrates the elements of a modulated hysteresis generator 30 that implements equation (5) using a squaring circuit 80 that may be implemented by using bipolar transistor's inherent logarithmic function of base-emitter voltage versus emitter current that is well known by the skilled in the art. Thus the squaring circuit 80 is followed by a level shifter and phase splitter 82, followed by a multiplexor 84 similar to the circuit illustrated in FIG. 5A or 5B. FIG. 5D illustrates a current squaring circuit where the collector current of transistor Q5 is equal to the square of current I1 divided by the current I2, assuming all the transistors Q2 to Q5 are identical. And the skilled in the art can translate voltages into currents using voltage-to-current converters and current mirrors, or translate currents into voltages using resistors.

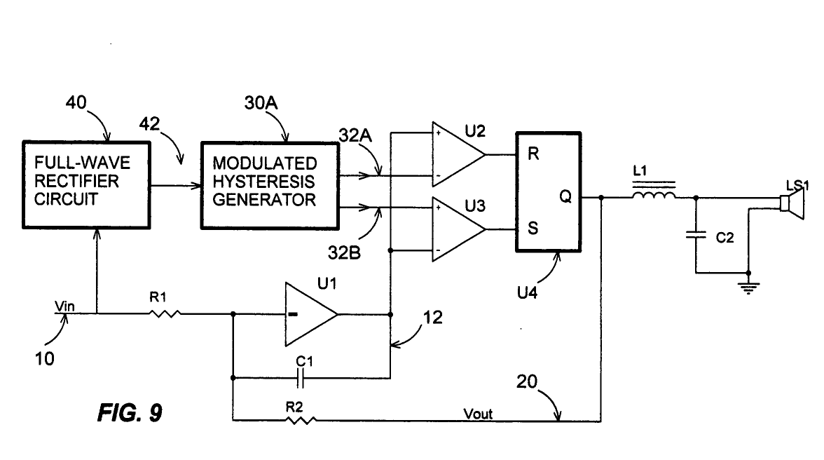

FIG. 9 illustrates an alternate embodiment of CFSOA slightly different from the embodiment illustrated in FIG. 3, wherein the function of the multiplexor 84 of the modulated hysteresis generator 30 of FIG. 5C is replaced by two comparators U2-U3 and an RS flipflop U4 to implement the operation illustrated in FIG. 4C, wherein the comparator U2 detects the moment the error voltage 12 hits the upper hysteresis threshold 32A and resets the RS flipflop U4, and wherein the comparator U3 detects the moment the error voltage 12 hits the lower threshold 32B and set the RS flipflop U4, see FIGS. 5B and 9.

The reader can see that by using just a few components to implement the modulation of the hysteresis of the comparator U2 according to the square of the magnitude of the input signal 10, the switching frequency of the invented CFSOA is practically constant, therefore the THD of this amplifier is greatly reduced while its bandwidth is essentially invariant with the amplitude of the input signal 10. The CFSOA's constant switching frequency also makes its other auxiliary circuits such as over-current protection easier to implement. For an audiophile, any variation of an amplifier audible characteristic is very undesirable, such as THD, bandwidth, transient response etc. Indeed, in an amplifier, a reduced bandwidth when the audio signal is high implies a crowding-out effect that occurs when a treble voice has its intensity reduced by a bass note with its usual high amplitude, i.e. a bass note crowds out the treble voice. It can also be said that if an amplifier's bandwidth depends on the amplitude of its input signal, then its transient response also depends on the amplitude of the input signal, in other words the amplifier is non-linear.

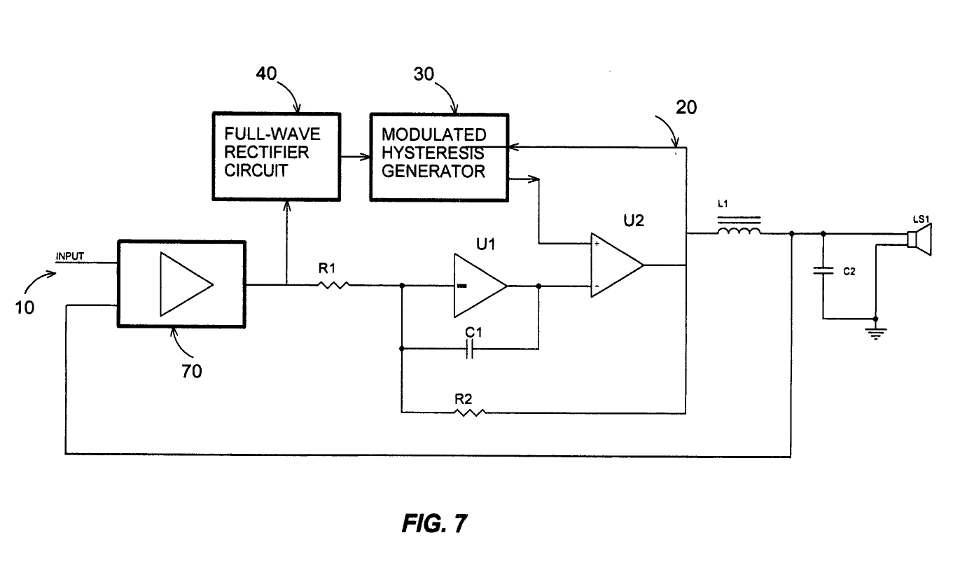

In another embodiment, FIG. 7, an additional gain block 70 is added to increase the open loop gain of the CFSOA, where the speaker voltage is fed back and compared to the input signal 10 to generate an error signal 71 that is now used as an input signal to an inner CFSOA of the first embodiment of FIG. 3. Of course the transfer function of such an additional gain stage needs to be tailored to maintain the closed loop stability. Techniques for loop stability are well known to the skilled in the art, essentially the design must have loop phase shift less than 360 degrees when the loop gain is unity. Typically the transfer function of the gain block 70 ought to have at least one zero in its transfer function so that it doesn't add substantial phase shift around 0 dB crossing of the open loop gain of the amplifier. The additional loop gain provided by the gain block 70 will further reduce the distortion of the CFSOA and its output impedance by its gain.

From the description above, a number of advantages of the invented constant frequency self-oscillating switch-mode amplifiers become evident:

(a) The absence of an independent sawtooth or triangular oscillator, which is a source of distortion and noise due to its frequency variation, non-linearity, and amplitude jitter, results in a simpler and lower cost circuit.

(b) The essentially constant switching frequency results in a linear amplifier having its bandwidth and its low harmonic distortion independent of the amplitude of input signal.

(c) The modulated hysteresis generator circuit is quite simple, therefore low cost.

(d) The output impedance of the amplifier is extremely low due to feedback being taken directly from speaker terminals and high loop gain-bandwidth.

### SUMMARY RAMIFICATION AND SCOPE

Accordingly the reader can see that the invented self-oscillating switch-mode amplifiers embodies many novel circuits all in the direction of higher bandwidth, lower distortion, and higher efficiency while keeping component count to a minimum.

Amplifiers are rather generic in terms of electronic circuit. They are fundamental building blocks of most analog electronic systems including servo control, inverter, motor drive, power supply voltage regulation, etc. . . . The self-oscillating switch-mode amplifier of the present invention can be used with minimum adaptation as a DC-to-AC converter, also called inverter, as a DC-to-DC converter, a switch-mode power supply (SMPS), an ultrasound generator—due to its high bandwidth in excess of 200 kHz in many configurations, variable frequency motor drive, etc. . . .

While the preferred embodiments of the present invention have been shown and described herein, it will be obvious that such embodiments are provided by way of example only. Numerous variations, changes, and substitutions will occur to those of skill in the art without departing from the spirit and scope of the invention herein. Therefore it must be understood that the illustrated embodiments have been set forth for the purposes of examples and it should not be taken as limiting the invention as defined by the following claims.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

In addition to the equivalents of the claimed elements, obvious substitutions now or later known to one with ordinary skill in the art are defined to be within the scope of the defined elements.

Thus the scope of the invention should be determined by the appended claims and their legal equivalents, rather than by the examples given.

What is claimed is:

1. A self-oscillating switch-mode amplifier amplifying an input signal into a power output signal comprising
an integrator for integrating the difference between the input signal and the output signal into an error signal,
a full-wave rectifier circuit for rectifying the input signal into a positive modulating signal,
a modulated hysteresis generator having for its two inputs the positive modulating signal and the output signal, for putting out a hysteretic signal to which the error signal is compared by a comparator,
wherein the envelopes of the hysteretic signal which are offset image and mirror image of each other reduce the range of variation of the switching frequency of the self-oscillating amplifier.

2. The self-oscillating amplifier of claim 1 wherein the modulated hysteresis generator comprises at least one voltage-to-current converter.

3. The self-oscillating amplifier of claim 1 wherein the modulated hysteresis generator comprises a phase splitter for supplying two voltage waveforms symmetrical to each other.

4. The self-oscillating amplifier of claim 1 wherein the modulated hysteresis generator comprises a multiplexer controlled by an output of the comparator.

5. The self-oscillating amplifier of claim 1 wherein the modulated hysteresis generator supplies a hysteretic voltage whose envelopes are non-linear function of the input signal.

6. The self-oscillating amplifier of claim 1 wherein the modulated hysteresis generator supplies a hysteretic voltage whose envelopes are quadratic function of the amplitude of the input signal.

7. The self-oscillating amplifier of claim 1 wherein the integrator additionally integrates a signal proportional to the speaker voltage.

8. The self-oscillating amplifier of claim 1 wherein the integrator additionally integrates a signal proportional to the output current of the amplifier.

9. The self-oscillating amplifier of claim 1 wherein the integrator is additionally preceded by an amplifier amplifying the difference of the input signal and the output signal.

10. The self-oscillating amplifier of claim 9 wherein the amplifier has at least one zero in its transfer function.

11. A self-oscillating switch-mode amplifier amplifying an input signal into a power output signal comprising
an integrator for integrating the difference between the input signal and the output signal into an error signal that has positive and negative sloped segments,
a full-wave rectifier circuit for rectifying the input signal into a positive modulating signal,
a modulated hysteresis generator receiving the positive modulating signal, for generating two mirrored modulated thresholds defining the hysteretic limits of the error signal,
two comparators and an associated flip-flop for generating a pulse-width-modulated signal,
wherein the two modulated thresholds which follow a predetermined function of the positive modulating signal reduce the range of variation of the switching frequency of the self-oscillating amplifier.

12. The self-oscillating amplifier of claim 11 wherein the two thresholds follow a quadratic function of the positive modulating signal.

13. The self-oscillating amplifier of claim 11 wherein the modulated hysteresis generator comprises squaring circuit and a phase splitter.

14. The self-oscillating amplifier of claim 13 wherein the squaring circuit comprises four bipolar transistors, two of which are in series and have their base shorted to their collector.

15. The self-oscillating amplifier of claim 11 wherein the integrator additionally integrates a signal proportional to the speaker voltage.

16. The self-oscillating amplifier of claim 11 wherein the integrator additionally integrates a signal proportional to the output current of the amplifier.

17. The self-oscillating amplifier of claim 11 wherein the integrator is additionally preceded by an amplifier amplifying the difference of the input signal and the output signal.

18. The self-oscillating amplifier of claim 17 wherein the amplifier has at least one zero in its transfer function.

19. A method for maintaining the switching frequency of an analog delta-sigma modulator having an input signal and an output signal, via modulated hysteresis thresholds, the method comprising squaring the input signal into a quadratic signal, phase-splitting the quadratic signal into two mirrored threshold signals, integrating the difference between the input signal and the output signal for obtaining an error signal, and compare the error signal to the two threshold signals to obtain a pulse-width-modulated signal whose frequency is substantially constant.

20. The method for maintaining the switching frequency of an analog delta-sigma modulator of claim 19, wherein the squaring of the input signal is via a current-mode current circuit comprising four bipolar transistors, two of which are in series and have their base shorted to their collector.
